(19) United States
(12) Patent Application Publication
(10) Pub. No.: US 2016/0172621 A1
(43) Pub. Date: Jun. 16, 2016

(54) ENCAPSULATION STRUCTURE, ORGANIC ELECTROLUMINESCENT DEVICE AND ENCAPSULATION METHOD THEREOF

(71) Applicant: BOE TECHNOLOGY GROUP CO., LTD., Beijing (CN)

(72) Inventors: Zhiqiang JIAO, Beijing (CN); Wenjun HOU, Beijing (CN); Guang YAN, Beijing (CN); Juanjuan YOU, Beijing (CN)

(21) Appl. No.: 14/436,840

(22) PCT Filed: Aug. 7, 2014
(86) PCT No.: PCT/CN2014/083912

§ 371 Date: Apr. 17, 2015

(30) Foreign Application Priority Data
Apr. 29, 2014 (CN) 201410180589.8

(51) Int. Cl. H01L 51/52; H01L 27/32; H01L 51/56

(52) U.S. Cl. CPC H01L 51/5246; H01L 51/56; H01L 27/3262; H01L 2251/558; H01L 27/1225

(57) ABSTRACT

An encapsulation structure, an organic electroluminescent device and an encapsulation method thereof are provided. The organic electroluminescent device comprises a substrate, an electroluminescent structure disposed on the substrate, a water/oxygen barrier bank (4) disposed on the substrate and arranged around the electroluminescent structure to form a closed ring structure, and a sealing thin film which covers the electroluminescent structure and a periphery of which is hermetically matched with the water/oxygen barrier bank. The organic electroluminescent device is conducive to the realization of the narrow-frame design of the organic electroluminescent device.

### TECHNICAL FIELD

At least one embodiment of the present disclosure relates to an encapsulation structure, an organic electroluminescent device and an encapsulation method thereof.

### BACKGROUND

The organic light-emitting diode (OLED) is an organic electroluminescent device and has the advantages of simple manufacturing process, low cost, high luminous efficiency, easy formation of a flexible structure, etc. Therefore, the display technology employing the OLED has become an important display technology.

The encapsulation technology of the OLED device is an important factor to affect the service life of the OLED device. Thin film sealing (thin film encapsulation) is a common encapsulation mode in the encapsulation of the OLED device and can satisfy the requirements for lighter and thinner OLED device. Therefore, many researchers pay attention to the thin film encapsulation.

As illustrated in FIGS. 1a and 1b, an OLED device comprises a substrate 01, an electroluminescent structure 02 and a sealing thin film 03. In order to limit and prevent oxygen and moisture from entering the OLED device, as illustrated in FIG. 1a, the periphery of the sealing thin film 03 needs to be hermetically matched with the substrate 01. However, if the sealing width d between the periphery of the sealing thin film 03 and the substrate 01 is too narrow, oxygen and moisture can penetrate the OLED device from the edge of the sealing thin film 03.

### SUMMARY

At least one embodiment of the present disclosure provides an encapsulation structure, an organic electroluminescent device and an encapsulation method thereof. In the organic electroluminescent device, the width of a structure for the sealing around the organic electroluminescent structure may be adjusted, so that the narrow-frame design of the OLED device can be achieved.

At least one embodiment of the present disclosure provides an electroluminescent device, which comprises: a substrate; an electroluminescent structure disposed on the substrate; a water/oxygen barrier bank disposed on the substrate and arranged around the electroluminescent structure to form a closed ring structure; and a sealing thin film which covers the electroluminescent structure and the periphery of which is hermetically matched with the water/oxygen barrier bank.

In another aspect, at least one embodiment of the present disclosure provides an encapsulation method of an electroluminescent device. The method comprises: forming an electroluminescent structure on a substrate; forming a water/oxygen barrier bank on the substrate, so that the water/oxygen barrier bank is disposed around the electroluminescent structure to form a closed ring structure; and forming a sealing thin film in a region encircled by the water/oxygen barrier bank, so that the sealing thin film covers the electroluminescent structure, and a periphery of the sealing thin film is hermetically matched with the water/oxygen barrier bank.

In still another aspect, at least one embodiment of the present disclosure further provides an encapsulation structure, which comprises: a substrate; a device to be encapsulated disposed on the substrate; a barrier bank disposed on the substrate and arranged around the device to be encapsulated to form a closed ring structure; and a sealing thin film which covers the device to be encapsulated and the periphery of which is hermetically matched with the barrier bank.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIGS. 1a and 1b are schematic structural views of an encapsulation structure of an organic electroluminescent device;

FIG. 2 is a schematic structural top view of an organic electroluminescent device provided by one embodiment of the present disclosure; and

FIG. 3 is an A-A sectional view of the organic electroluminescent device having the structure as shown in FIG. 2.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

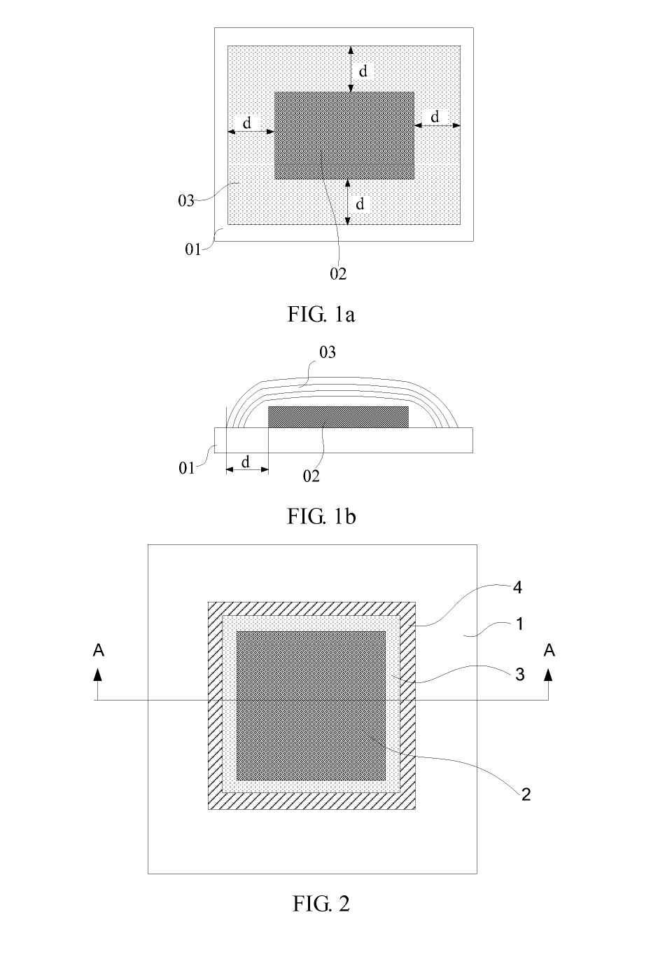

The inventor of the application noted that: in the encapsulation structure of the organic electroluminescent device as shown in FIGS. 1a and 1b, in order to ensure the effectiveness of the sealing between the sealing thin film 03 and the substrate 01 for the electroluminescent structure 02, the sealing width d between the periphery of the sealing thin film 03 and the substrate 01 needs be guaranteed. For instance, in the thin film encapsulation technology, the width d is 5 mm, but this makes it difficult for the OLED device encapsulated using the sealing thin film 03 to achieve a narrow-frame design.

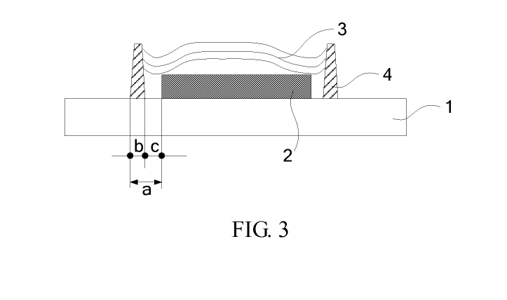

FIG. 2 is a schematic structural top view of an organic electroluminescent device provided by one embodiment of the present disclosure. FIG. 3 is an A-A sectional view of the organic electroluminescent device having the structure as shown in FIG. 2.

As illustrated in FIGS. 2 and 3, the organic electroluminescent device provided by at least one embodiment of the present disclosure comprises: a substrate 1, an electroluminescent structure 2, a sealing thin film 3 and a water/oxygen barrier bank 4. The electroluminescent structure 2 is disposed on the substrate 1; the water/oxygen barrier bank 4 is disposed on the substrate 1 and arranged around the electroluminescent structure 2 to form a closed ring structure, as illustrated in FIG. 2. The sealing thin film 3 covers the electroluminescent structure 2, and the periphery of the sealing thin film 3 is hermetically matched with the water/oxygen barrier bank 4.

In the organic electroluminescent device, as illustrated in FIG. 2, the water/oxygen barrier bank 4 on the substrate 1 has a closed ring structure; and the electroluminescent structure 2 is disposed in a region encircled by the water/oxygen barrier bank 4. The water/oxygen barrier bank 4 may realize blocking oxygen and water and is hermetically matched with the periphery of the sealing thin film 3 for sealing the electroluminescent structure 2, so that the sealing around the electroluminescent structure 2 can be realized by the water/oxygen barrier bank 4.

As illustrated in FIG. 3, after the encapsulation of the organic electroluminescent device, the width a of a region disposed on the periphery of the electroluminescent structure 2 and configured to encapsulate the electroluminescent structure is the sum of the thickness b of a bank body of the water/oxygen barrier bank 4 and the width c of a gap between the water/oxygen barrier bank 4 and the periphery of the electroluminescent structure 2. In the water/oxygen barrier bank 4, the thickness b of the bank body of the water/oxygen barrier bank 4 in the direction from the inside to the outside of the closed ring structure formed by the water/oxygen barrier bank 4 may be set according to design requirement, as long as oxygen and moisture are blocked, and the width c of the gap between the water/oxygen barrier bank 4 and the periphery of the electroluminescent structure 2 may be set according to design requirement, so when the thickness b of the bank body of the water/oxygen barrier bank 4 is designed to be smaller and the width c of the gap between the water/oxygen barrier bank 4 and the periphery of the electroluminescent structure 2 is designed to be smaller, the frame of the organic electroluminescent device is narrower. Therefore, the organic electroluminescent device is conducive to the realization of the narrow-frame design of the organic electroluminescent device.

In various embodiments, as for the water/oxygen barrier bank 4 of the organic electroluminescent device, the thickness b of the bank body of the water/oxygen barrier bank 4 in the direction from the inside to the outside of the closed ring structure formed by the water/oxygen barrier bank 4 may be from 0.5 mm to 1.5 mm, e.g., 0.5 mm, 0.7 mm, 0.8 mm, 1.0 mm, 1.2 mm, 1.3 mm and 1.5 mm.

When the thickness b of the bank body of the water/oxygen barrier bank 4 is from 0.5 mm to 1.5 mm, not only requirement, for blocking the oxygen and moisture, of the water/oxygen barrier bank 4 can be satisfied, but also the narrow-frame design of the organic electroluminescent device can be made easy to achieve.

In various embodiments, the width c of the gap between the water/oxygen barrier bank 4 and the electroluminescent structure 2 may be from 0 mm to 3 mm, e.g., 0 mm, 0.2 mm, 0.5 mm, 1.0 mm, 1.2 mm, 1.5 mm, 1.7 mm, 2.0 mm, 2.2 mm, 2.5 mm, 2.7 mm, 2.9 mm and 3.0 mm.

In one embodiment, the width c of the gap between the water/oxygen barrier bank 4 and the electroluminescent structure 2 is 1.5 mm. When the above-mentioned width c of the gap between the water/oxygen barrier bank 4 and the electroluminescent structure 2 is 1.5 mm, not only the narrow-frame design of the organic electroluminescent device can be made easy to achieve, but also the contact between the water/oxygen barrier bank 4 and the electroluminescent structure 2 can be avoided to prevent the water/oxygen barrier bank 4 from polluting the electroluminescent structure 2.

When the water/oxygen barrier bank 4 is set according to the above mode, the width a of the region, provided around the electroluminescent structure 2 in the organic electroluminescent device and used for sealing, may be from 0.5 mm to 4.5 mm, so that the frame of the organic electroluminescent device can be narrower.

In one embodiment, the water/oxygen barrier bank 4 may be a water/oxygen barrier bank formed through a solidified sealant. Because the water/oxygen barrier bank 4 is formed through the solidified sealant (frame sealant), the stability of the connection between the water/oxygen barrier bank 4 and the substrate 1 can be improved, and further the stability of the encapsulation structure of the organic electroluminescent device can be improved.

In one embodiment, the substrate 1 may be an oxide thin film transistor substrate or a low temperature poly-silicon substrate.

In one embodiment, the electroluminescent structure 2 may be a monochromic light-emitting structure or a multicolor light-emitting structure.

As illustrated in FIG. 3, in one embodiment, the sealing thin film 3 may include: a plurality of organic sealing layers; or a plurality of inorganic sealing layers; or a plurality of organic sealing layers and a plurality of inorganic sealing layers. For instance, the inorganic sealing layers and the organic sealing layers are overlapped with each other.

In another aspect, at least one embodiment of the present disclosure further provides an encapsulation method for the organic electroluminescent device provided by any one of the above embodiments. The method comprises: forming an electroluminescent structure on a substrate, in which step the electroluminescent structure may be formed on the substrate through various processes, e.g., evaporation process; forming a water/oxygen barrier bank on the substrate, so that the water/oxygen barrier bank is disposed around the electroluminescent structure and forms a closed ring structure; and forming a sealing thin film in a region encircled by the water/oxygen barrier bank, so that the sealing thin film covers the electroluminescent structure, and the periphery of the sealing thin film is hermetically matched with the water/oxygen barrier bank.

In the encapsulation method of the organic electroluminescent device, the thickness of the bank body of the water/oxygen barrier bank in the direction from the inside to the outside of the closed ring structure formed by the water/oxygen barrier bank may be set according to design requirements, as long as oxygen and moisture can be blocked, and the width of the gap between the water/oxygen barrier bank and the periphery of the electroluminescent structure may be set according to design requirements. Therefore, the encapsulation method is conducive to the manufacturing of the narrow-frame organic electroluminescent device.

In one embodiment, the step of forming the water/oxygen barrier bank on the substrate may include: coating a sealant around the electroluminescent structure so that the sealant forms the closed ring structure; and performing, for instance, an ultraviolet light solidifying process on the coated sealant to form the water/oxygen barrier bank.

At least one embodiment of the present disclosure further provides an encapsulation structure, which comprises: a substrate; a device to be encapsulated which is disposed on the substrate; a barrier bank disposed on the substrate and arranged around the device to be encapsulated so as to form a closed ring structure; and a sealing thin film which covers the device to be encapsulated and the periphery of which is hermetically matched with the barrier bank. The encapsulation structure provided by the embodiment of the present disclosure is applicable to a device adopting a sealing thin film for encapsulation and particularly applicable to a device requiring a narrow-frame design and adopting a sealing thin film for encapsulation.

The barrier bank and the sealing thin film in the embodiment of the present disclosure may be designed according to actual requirements. For instance, the device to be encapsulated may be an optoelectronic device, e.g., an organic light-emitting diode, an inorganic light-emitting diode, an organic solar cell, an inorganic solar cell, an organic thin film transistor, an inorganic thin film transistor and a photodetector. These optoelectronic devices are sensitive to oxygen and moisture, so the optoelectronic devices needs to be protected by adopting the encapsulation technology. At this point, the barrier bank may be a water/oxygen barrier bank which may be formed by performing, for instance, an ultraviolet light solidifying process on a sealant.

In the encapsulation structure provided by the embodiment of the present disclosure, the thickness of the bank body of the barrier bank in the direction from the inside to the outside of the closed ring structure formed by the barrier bank may be set according to design requirements, and the width of the gap between the barrier bank and the periphery of the device to be encapsulated may be set according to design requirements, so when the thickness of the bank body of the barrier bank is designed to be smaller and the width of the gap between the barrier bank and the periphery of the device to be encapsulated is designed to be smaller, the frame of the encapsulation structure is narrower. The width of the structure for the sealing around the device to be encapsulated, in the encapsulation structure, can be adjusted, so the encapsulation structure is conducive to the realization of the narrow-frame design.

Obviously, various variations and modifications can be made to the embodiments of the present disclosure by those skilled in the art without departing from the spirit and scope of the present disclosure. Therefore, if these variations and modifications for the present disclosure fall within the scope of the appended claims of the present disclosure and equivalents thereof, the present disclosure is also intended to cover these variations and modifications.

The application claims priority to the Chinese Patent Application No. 201410180589.8, filed on Apr. 29, 2014, which is hereby entirely incorporated by reference as a part of the application.

1. An organic electroluminescent device, comprising:
a substrate;
an electroluminescent structure, disposed on the substrate;
a water/oxygen barrier bank, disposed on the substrate and arranged around the electroluminescent structure to form a closed ring structure; and
a sealing thin film, covering the electroluminescent structure, wherein a periphery of the sealing thin film is hermetically matched with the water/oxygen barrier bank.

2. The organic electroluminescent device according to claim 1, wherein a thickness of a bank body of the water/oxygen barrier bank is from 0.5 mm to 1.5 mm in a direction from an inside to an outside of the closed ring structure formed by the water/oxygen barrier bank.

3. The organic electroluminescent device according to claim 1, wherein a width of a gap between the water/oxygen barrier bank and the electroluminescent structure is from 0 mm to 3 mm.

4. The organic electroluminescent device according to claim 1, wherein a width of a gap between the water/oxygen barrier bank and the electroluminescent structure is 1.5 mm.

5. The organic electroluminescent device according to claim 1, wherein the water/oxygen barrier bank is a water/oxygen barrier bank formed by solidified sealant.

6. The organic electroluminescent device according to claim 1, wherein the substrate is an oxide thin film transistor substrate or a low temperature polycrystalline silicon substrate.

7. The organic electroluminescent device according to claim 1, wherein the electroluminescent structure is a monochromatic light-emitting structure or a multicolor light-emitting structure.

8. The organic electroluminescent device according to claim 1, wherein the sealing thin film comprises:
a plurality of organic sealing layers; or
a plurality of inorganic sealing layers; or
a plurality of organic sealing layers and a plurality of inorganic sealing layers, wherein the inorganic sealing layers and the organic sealing layers are overlapped with each other.

9. An encapsulation method of an organic electroluminescent device, comprising:
forming an electroluminescent structure on a substrate;
forming a water/oxygen barrier bank on the substrate, wherein the water/oxygen barrier bank is disposed around the electroluminescent structure to form a closed ring structure; and
forming a sealing thin film in a region encircled by the water/oxygen barrier bank, wherein the sealing thin film covers the electroluminescent structure, and a periphery of the sealing thin film is hermetically matched with the water/oxygen barrier bank.

10. The encapsulation method according to claim 9, wherein forming the water/oxygen barrier bank on the substrate comprises:
coating a sealant around the electroluminescent structure so that the sealant forms the closed ring structure; and
performing a solidifying process on the sealant coated, to form the water/oxygen barrier bank.

11. The encapsulation method according to claim 10, wherein the solidifying process comprises an ultraviolet light solidifying process.

12. An encapsulation structure, comprising:
a substrate;
a device to be encapsulated, disposed on the substrate;
a barrier bank, disposed on the substrate, and arranged around the device to be encapsulated to form a closed ring structure; and
a sealing thin film, covering the device to be encapsulated, wherein a periphery of the sealing thin film is hermetically matched with the barrier bank.

13. The organic electroluminescent device according to claim 2, wherein a width of a gap between the water/oxygen barrier bank and the electroluminescent structure is from 0 mm to 3 mm.

14. The organic electroluminescent device according to claim 2, wherein a width of a gap between the water/oxygen barrier bank and the electroluminescent structure is 1.5 mm.

15. The organic electroluminescent device according to claim 3, wherein the width of the gap between the water/oxygen barrier bank and the electroluminescent structure is 1.5 mm.

16. The organic electroluminescent device according to claim 2, wherein the water/oxygen barrier bank is a water/oxygen barrier bank formed by solidified sealant.

17. The organic electroluminescent device according to claim 3, wherein the water/oxygen barrier bank is a water/oxygen barrier bank formed by solidified sealant.

18. The organic electroluminescent device according to claim 4, wherein the water/oxygen barrier bank is a water/oxygen barrier bank formed by solidified sealant.

19. The organic electroluminescent device according to claim 2, wherein the substrate is an oxide thin film transistor substrate or a low temperature polycrystalline silicon substrate.

20. The organic electroluminescent device according to claim 3, wherein the substrate is an oxide thin film transistor substrate or a low temperature polycrystalline silicon substrate.
